(19) United States
(12) Patent Application Publication
(10) Pub. No.: US 2010/0205342 A1
(43) Pub. Date: Aug. 12, 2010

(54) FUNCTION EXPANSION METHOD FOR ELECTRONIC PRODUCT AND DEVICE THEREOF

(76) Inventor: Nai-Chien CHANG, Sanchong City (TW)

Correspondence Address: HDLS Patent & Trademark Services, P.O. BOX 220746, CHANTILLY, VA, 20153-0746, US

(21) Appl. No.: 12/637,049

(22) Filed: Dec. 14, 2009

(30) Foreign Application Priority Data
Feb. 12, 2009 (TW) 098104534

(51) Int. Cl. G06F 13/00; H05K 7/10

(52) U.S. Cl. 710/301

(57) ABSTRACT

In a function expansion method for an electronic product and a device thereof, the device includes a circuit board, a microprocessor unit and a storage unit. The circuit board includes an expansion socket, and the expansion socket includes a plurality of plugholes. The microprocessor unit is installed onto the circuit board and electrically coupled to the each plughole. The storage unit is installed onto the circuit board and electrically coupled to the microprocessor unit. The microprocessor unit scans a predetermined plughole group installed on the expansion socket to determine whether or not a functional device is plugged, and then determines what type of functional device is plugged into the plughole group, and finally reads a driver program of the functional device from storage unit, and the functional device is installed or driven.

### BACKGROUND OF THE INVENTION

1. Field of the Invention

The present invention relates to a function expansion, and more particularly to a function expansion method for an electronic product and a device thereof.

2. Description of Prior Art

At present, all electronic products are equipped with a circuit board for combining electronic components to provide various different functions according to the functions of electric appliances or electronic products, such that the electric appliance products have the desired functions including auto On/Off, timer, time display, time adjustment, light control, temperature setting, temperature reservation, detection, temperature modulation, video-recording, video-playing, and remote control, etc. After these electric appliance products have the basic functions, the products at most can connect to an external load (such as a speaker, a printer, and a hard disk, etc) for driving the load to operate, but they cannot provide other function expansions for the electric appliances or electronic products.

Since science and technology advance continuously in recent years, panels installed on some refrigerators also come with a display screen electrically coupled to a circuit board, and a plurality of sensors electrically coupled to the circuit board for detecting storage temperature, quantity of food or beverage, or defrost status, etc, and transmitting corresponding sensing signals to the circuit board for their processing, and the processed results including data and graphics are displayed from the display screen, so that users can know about the using status of the refrigerators. The display screen comes with not other function, and the installation of a display screen onto the refrigerator is not just a stunt only, but also is a marketing measure.

For example, household lamps are turned on or off by a control of switches, and which light bulb to be turned on or off can be controlled during the switching process, so that users can selectively use the lamps. If a user wants to control the light bulb of the lamp to produce various blinking effects, then the user has to modify the lamp by installing an additional control circuit board or connecting the lamp to an external computer, and using signals outputted from the control circuit board or computer to control different blinking effects of the lamp. Some users may replace the whole set of lamp instead. Obviously, such arrangement causes a substantial modification and incurs a high cost, and thus the prior art requires improvements.

### SUMMARY OF THE INVENTION

Therefore, it is a primary objective of the present invention to provide a function expansion device operated together with an electronic product, such that users simply plug the functional device into an expansion socket installed on the circuit board for an expansion to upgrade the electric appliances or electronic products or enhance their functions.

To achieve the foregoing objective, the present invention provides a function expansion device for an electronic product, comprising: a circuit board, a microprocessor unit and a storage unit. The circuit board includes an expansion socket installed thereon, and a plurality of plugholes formed on the expansion socket. The microprocessor unit is installed onto the circuit board and electrically coupled to each plughole for controlling the operation of the electronic product and scanning and determining a functional device that is plugged into the expansion socket. The storage unit is installed onto the circuit board and electrically coupled to the microprocessor unit for storing driver programs of the electronic products and different functional devices.

The invention also provides a function expansion method for an electronic product, and the method comprises the steps of: using a microprocessor unit to scan a predetermined plughole group installed in the expansion socket; determining whether or not the plughole group has a functional device installed thereon; determining what type of functional device is plugged into the plughole group; reading a driver program of the functional device from a storage unit; and installing or driving the functional device.

### BRIEF DESCRIPTION OF DRAWINGS

FIG. 1 is a schematic view of a first preferred embodiment of the present invention;

FIG. 2 is a schematic view of a second preferred embodiment of the present invention;

FIG. 3 is a schematic view of a plughole group (shaded grids) as depicted in FIG. 2;

FIG. 4 is a schematic view of a third preferred embodiment of the present invention;

FIG. 5 is a schematic view of a plughole group (shaded grids) as depicted in FIG. 4;

FIG. 6 is a schematic view of a fourth preferred embodiment of the present invention;

FIG. 7 is a schematic view of a plughole group (shaded grids) as depicted in FIG. 6; and

FIG. 8 is a flow chart of a function expansion method for an electronic product in accordance with the present invention.

### DETAILED DESCRIPTION OF THE INVENTION

The technical characteristics, features and advantages of the present invention will become apparent in the following detailed description of the preferred embodiments with reference to the accompanying drawings. The drawings are provided for reference and illustration only, but not intended for limiting the present invention.

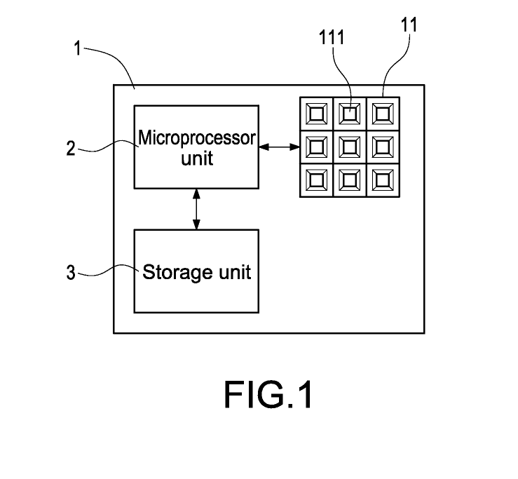

With reference to FIG. 1 for a schematic view of a first preferred embodiment of the present invention, a function expansion device for an electronic product comprises: a circuit board 1, a microprocessor unit 2 and a storage unit 3.

The circuit board 1 includes an expansion socket 11 installed thereon, and the expansion socket 11 includes plugholes 111 arranged in a 3×3 matrix or any other matrix, and a plughole group having any two plugholes among the plugholes 111 or any two or more plugholes, or any column of plugholes, any row of plugholes or diagonal plugholes is used for setting a functional device, and the set plughole group can be used for plugging a functional device (not shown in the figure).

The microprocessor unit 2 is electrically coupled to the plugholes 111 for controlling the electronic product to execute different functions, as well as determining the functions that the functional device plugged into the expansion socket 11 has.

The storage unit 3 is electrically coupled to the microprocessor unit 2 for storing different specifications or driver programs of the functional device designated for the plughole group, wherein the storage unit 3 shown in the figure is a memory device.

Therefore, the expansion socket 11 of the circuit board 1 allows users to perform a function expansion, if needed.

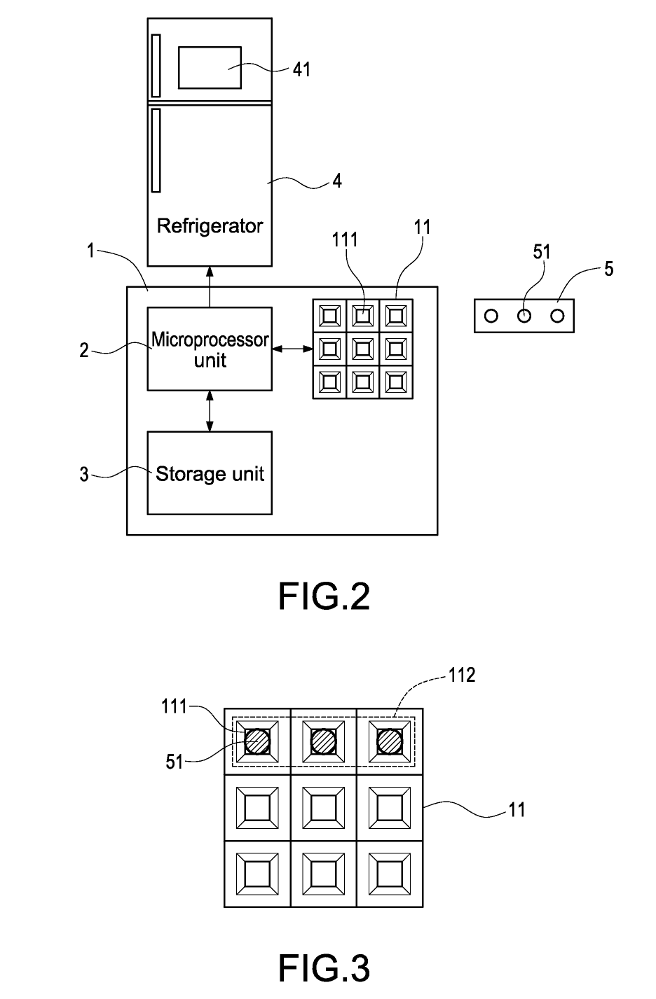

With reference to FIGS. 2 and 3 for schematic views of a second preferred embodiment of the present invention and a plughole group (shaded grids) as depicted in FIG. 2 respectively, when the circuit board 1 is installed to the refrigerator 4 having a small display screen 41, the display screen 41 is controlled by the microprocessor unit 2 of the circuit board 1 to play multimedia data (advertising or related product information) stored in the storage unit 3 on the display screen 41, or display the current condition of frozen food stored in the refrigerator 4.

If a user wants to execute a wireless transmission or receiving function from the refrigerator 4, the user can plug a plurality of pins 51 of the functional device having a wireless module 5 as shown in FIG. 3 into three shaded grids 112 at the uppermost layer, and then the microprocessor unit 2 determines whether the wireless module is a Bluetooth wireless module or a wireless area network, and the microprocessor unit 2 reads a driver program of the Bluetooth wireless module or the wireless area network from the storage unit 3, such that the refrigerator 4 can carry out a wireless remote control of transmitting data or downloading data from a network via a wireless transmission. For example, one's picture or family's picture can be processed by a computer or any other peripheral, the processed data are transmitted via a wireless transmission and received by the wireless module 5, so that the data can be played or displayed on the display screen 41 of the refrigerator 4.

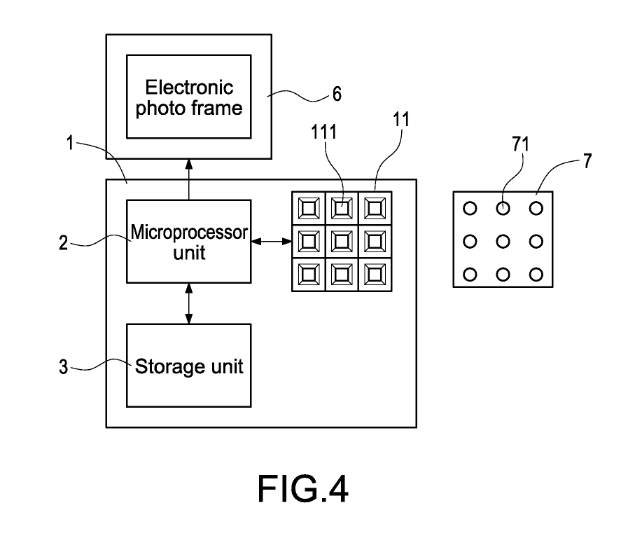

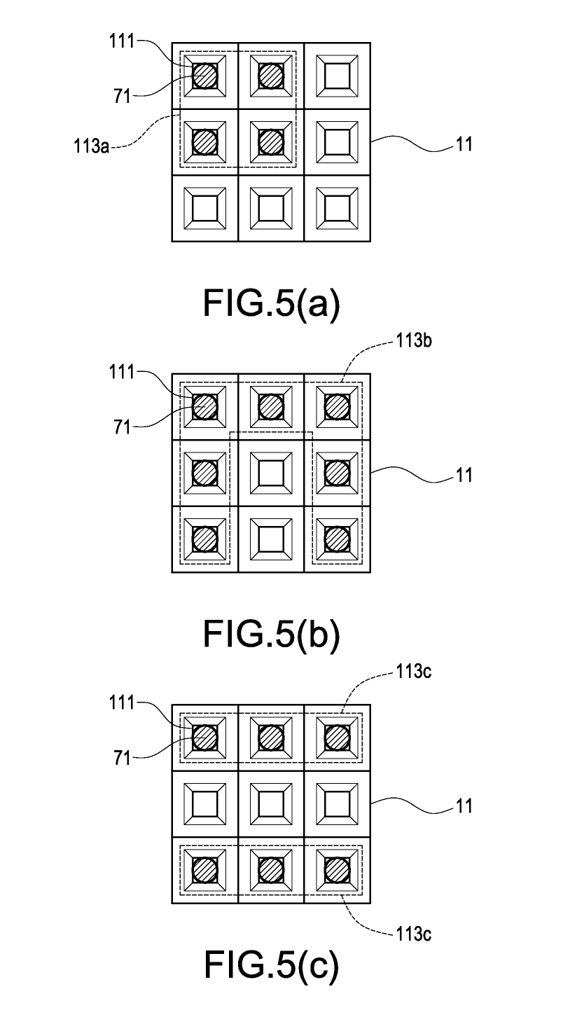

With reference to FIGS. 4 and 5 for schematic views of a third preferred embodiment of the present invention and each type of plughole group (shaded grids) as depicted in FIG. 4 respectively, when the circuit board 1 electrically coupled to an electronic clock 6 is used and controlled by the microprocessor unit 2, the display of time of the electronic clock 6 can be controlled and other functions can be set.

If a user wants to add an electric connector on an electronic photo frame 6, and the functional device has a multi-interface multi-port electric connector 7 or a single-interface electric connector, and a plurality of pins 71 of the multi-port electric connector 7 are inserted into the plugholes 111 of the expansion socket 11 respectively, and the microprocessor unit 2 determines that the four shaded grids 113a of the plughole group are USB electric connectors (as shown in FIG. 5a), then the microprocessor unit 2 will read or execute a USB electric connector driver program stored in the storage unit 3. If it is necessary to show different changes of image displays from the electronic photo frame 6, the USB electric connector electrically coupled to an external computer or flash disk will control the program input and store the program into the storage unit 3, so that the program can control the electronic photo frame 6 to play or display the image by different display methods.

If the microprocessor unit 2 determines that the plugged plughole group including seven shaded grids 113b is an IE1394 electric connector (as shown in FIG. 5b), the microprocessor unit 2 will read or execute an IE1394 electric connector driver program stored in the storage unit 3.

If the microprocessor unit 2 determines that the plugged plughole group including six shaded grids 113c is an eSATA electric connector (as shown in FIG. 5 c), the microprocessor unit 2 will read or execute an eSATA electric connector driver program stored in the storage unit 3.

Therefore, users can use a multi-port connector to transmit various different data such as MP3, MP4, and WAV data, etc, so that the electronic photo frame 6 can play multimedia data.

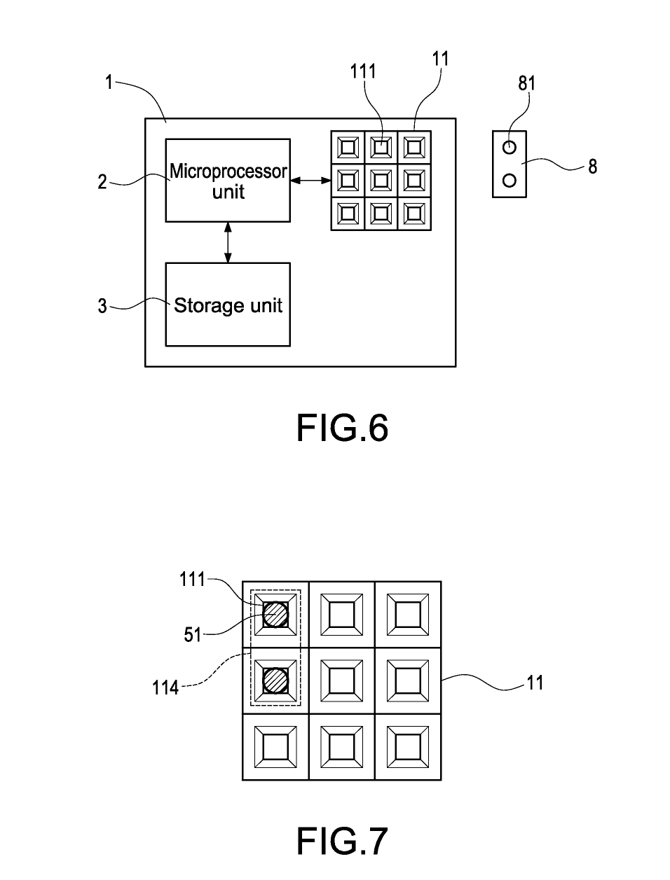

With reference to FIGS. 6 and 7 for schematic views of a fourth preferred embodiment of the present invention and a plughole group (shaded grids) as depicted in FIG. 6 respectively, if the circuit board 1 is electrically coupled to a certain electronic product, and the storage unit 3 installed on the circuit board 1 has insufficient capacity, users can plug a pin 81 of the functional device which is a storage unit module 8 into a plughole 11 of the expansion socket 11, and the microprocessor unit 2 determines that the plughole group is a storage unit module 8 (such as the two shaded grids 114 as shown in FIG. 7), the microprocessor unit 2 will read related data from the storage unit 3 to drive the storage unit module 8 to save and read data, so as to increase the storage capacity of the electronic product.

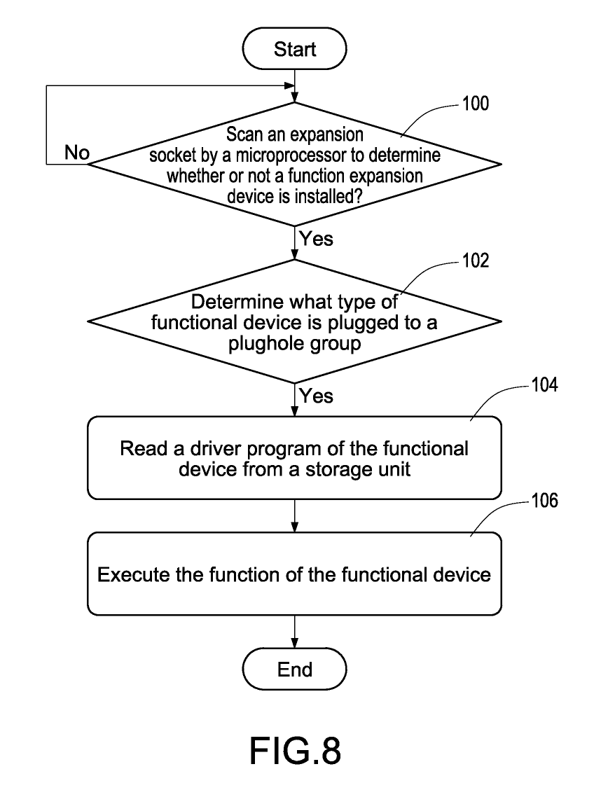

With reference to FIG. 8 for a flow chart of a function expansion method for an electronic product in accordance with the present invention, a circuit board 1 of the present invention is electrically coupled to an electronic product. In Step 100, a microprocessor unit scans an expansion socket to determine whether or not a functional device is installed. If yes, then the expansion socket will be scanned. If it is determined that the expansion socket is plugged with a functional device, then Step 102 will be executed to determine what type of functional device is plugged into a plughole group, and then Step 104 will be executed to read a driver program of the functional device from a storage unit, and finally Step 106 will be executed to carry out the functions of the functional device, so as to complete the function expansion of the electronic product.

In addition to the storage of various specification data or driver programs, the storage unit 3 of the circuit board 1 of the present invention also can store internal resistances of different pins of the functional device, and the internal resistances are determined by the microprocessor unit 2, such that we can know what functions the functional device carries.

The present invention is illustrated with reference to the preferred embodiment and not intended to limit the patent scope of the present invention. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A function expansion device for an electronic product, for inserting a pin of the function expansion device of the electronic product, and the functional expansion device comprising:
a circuit board, having an expansion socket installed thereon, and a plurality of plugholes disposed on the expansion socket;
a microprocessor unit, installed on the circuit board, and electrically coupled to each plughole of the expansion socket, for controlling an operation of the electronic product and scanning and determining a functional device connected to the expansion socket;
a storage unit, installed on the circuit board, and electrically coupled to the microprocessor unit, for storing a plurality of functional device driver programs of the electronic product.

2. The function expansion device of claim 1, wherein the plurality of plugholes are arranged in a 3×3 matrix.

3. The function expansion device of claim 1, wherein a plughole group having any two plugholes or any two or more plugholes in the plurality of plugholes is used for identifying the functional device and provided for plugging the functional device.

4. The function expansion device of claim 1, wherein an internal resistance of a pin of the functional device is determined to decide the type of the functional device.

5. The function expansion device of claim 1, wherein a plughole group having any column of plugholes, any row of plugholes, any diagonal plugholes in the plurality of plugholes is used for identifying the functional device, and provided for plugging the functional device.

6. The function expansion device of claim 1, wherein the functional device is a wireless module.

7. The function expansion device of claim 1, wherein the functional device is a storage unit module.

8. The function expansion device of claim 1, wherein the functional device is a multi-interface multi-port electric connector.

9. The function expansion device of claim 1, wherein the functional device is a single-interface electric connector.

10. The function expansion device of claim 1, wherein the storage unit is a memory device.

11. A function expansion method for an electronic product, the electronic product including a circuit board, and the circuit board being electrically coupled to an expansion socket with a plurality of plugholes, a microprocessor unit and a storage unit, and the microprocessor unit being electrically coupled to the storage unit and plurality of plugholes, and the method comprising the steps of:
using the microprocessor unit to scan a predetermined plughole group installed on the expansion socket;
determining whether or not the plughole group is plugged with a functional device;
determining what type of the functional device is plugged into the plughole group;
reading a driver program of the functional device from the storage unit, after the determination takes place, and executing a function of installing or driving the functional device.

12. The function expansion method of claim 11, wherein the plurality of plugholes are arranged into a 3×3 matrix.

13. The function expansion method of claim 11, wherein the plughole group having any two plugholes or any two or more plugholes in the plurality of plugholes is used for identifying the functional device, and provided for plugging the functional device.

14. The function expansion method of claim 11, wherein an internal resistance of a pin of the functional device is determined to decide the type of the functional device.

15. The function expansion method of claim 11, wherein a plughole group having any column of plugholes, any row of plugholes, any diagonal plugholes in the plurality of plugholes is used for identifying the functional device, and provided for plugging the functional device.

16. The function expansion method of claim 11, wherein the functional device is a wireless module.

17. The function expansion method of claim 11, wherein the functional device is a storage unit module.

18. The function expansion method of claim 11, wherein the functional device is a multi-interface multi-port electric connector.

19. The function expansion method of claim 11, wherein the functional device is a single-interface electric connector.

20. The function expansion method of claim 11, wherein the storage unit is a memory device.
